(19) United States
(12) Patent Application Publication
(10) Pub. No.: US 2009/0021685 A1
(43) Pub. Date: Jan. 22, 2009

(54) DISPLAY PANEL AND METHOD FOR THE SAME

(75) Inventors: Hendrik LOUWSMA, Heerlen (NL); Charles Schmidgall, Swalmen (NL)

Correspondence Address: VENABLE LLP, P.O. BOX 34385, WASHINGTON, DC, 20043-9998, US

(73) Assignee: TPO Displays Corp., Chu-Nan (TW)

(21) Appl. No.: 12/054,141

(22) Filed: Mar. 24, 2008

Related U.S. Application Data
(60) Provisional application No. 60/950,729, filed on Jul. 19, 2007.

(51) Int. Cl. G02F 1/1339; H01J 9/24

(52) U.S. Cl. 349/156; 445/24

(57) ABSTRACT

A method for forming a display panel including the following steps is provided. A substrate is provided. A plurality of barrier patterns are formed on the substrate. A planar structure is formed over the plurality of barrier patterns. A plurality of pixel elements and/or a plurality of array metals are formed over the planar structure. The planar structure has a thickness between 10 μm and 200 μm.

### TECHNICAL FIELD

The present invention relates to a display panel and a method for the same, and more particularly to a display panel with a barrier and a method for the same.

### BACKGROUND OF THE INVENTION

Multiple views of a display panel may be achieved via a barrier. Conventionally, the barrier, the pixel elements (e.g. the color filters or the light emitting diodes), and the array circuit (e.g. the thin film transistors) are respectively realized on separate substrates and then assembled with each other. The manufacture is complicated and a large number of components are involved.

However, the conventional substrate/substrates thus exists/exist between the pixel elements and the barrier may affect the viewing angle. The thickness of the substrate determines the distance between the pixel elements and the barrier. Referring to FIG. 1, pixel elements 610a and a barrier 604 are separated by a substrate 620 and thus have a distance d₁ therebetween. The substrate 620 may be the substrate on which the pixel elements formed or the barrier formed. The views 1 and 2 in FIG. 1 have narrow viewing angles since the distance d₁ between the pixel elements 610a and the barrier 604 is large, such as 500 μm. Namely a thick substrate may result in a narrow viewing angle. The substrate may be thinned before the assembly to reduce the resulted distance. Nevertheless, it further complicates the manufacture.

Therefore, a display panel having wider viewing angle for multiple views and simplified manufacture and a method of the same are needed.

### SUMMARY OF THE INVENTION

One object of the present invention is to provide a display panel having wider viewing angle for multiple views and simplified manufacture and a method of the same.

One aspect of the present invention provides a method for forming a display panel including the following steps. A substrate is provided. A plurality of barrier patterns are formed on the substrate. A planar structure is formed over the plurality of barrier patterns. A plurality of pixel elements and/or a plurality of array metals are formed over the planar structure. The planar structure has a thickness between 10 μm and 200 μm.

The step of forming the planar structure mentioned above may include the following steps. An adhesion material is applied around the plurality of barrier patterns. The planar structure is placed over the plurality of barrier patterns. The planar structure is adhered to the substrate by the adhesion material. The step of placing the planar structure over the plurality of barrier patterns may be performed under low pressure or vacuum, so that the planar structure contacts the plurality of barrier patterns. A plurality of spacers may be disposed on the substrate before the step of placing the planar structure over the plurality of barrier patterns. The planar structure may include plastic, glass, or a combination thereof.

The step of forming the planar structure mentioned above may include the following steps. An adhesion material is applied on the plurality of barrier patterns. The planar structure is placed on the adhesion material. The planar structure may include plastic, glass, or a combination thereof. The adhesion material may include optical glue, light curable glue, heat curable glue, or a combination thereof. The planar structure may be plastic and the step of placing the planar structure on the adhesion material may include hot pressing the planar structure toward the plurality of barrier patterns.

The step of forming the planar structure mentioned above may include depositing the planar structure over the plurality of barrier patterns and may further include polishing the planar structure. The planar structure may include organic transparent material. The step of depositing the planar structure over the plurality of barrier patterns may include screen-printing, spin coating, evaporation, sputtering, or a combination thereof.

Another aspect of the present invention provides a display panel. The display panel includes a substrate, a plurality of barrier patterns on the substrate, a planar structure over the plurality of barrier patterns, and a plurality of pixel elements and/or a plurality of array metals over the planar structure. The planar structure has a thickness between 10 μm and 200 μm.

The display panel mentioned above may further include an adhesion material around the plurality of barrier patterns. The planar structure may be adhered to the substrate by the adhesion material. The planar structure mentioned above may contact the plurality of barrier patterns. The display panel may further include a plurality of spacers disposed on the substrate. The planar structure may include plastic, glass, or a combination thereof.

The display panel mentioned above may further include an adhesion material on the plurality of barrier patterns. The planar structure may be placed on the adhesion material. The planar structure may include plastic, glass, or a combination thereof. The adhesion material includes optical glue, light curable glue, heat curable glue, or a combination thereof. The planar structure may be plastic and hot pressed toward the plurality of barrier patterns.

The planar structure mentioned above may be deposited over the plurality of barrier patterns. The planar structure may be further polished. The planar structure may include organic transparent material. The planar structure may be deposited over the plurality of barrier patterns by screen-printing, spin coating, evaporation, sputtering, or a combination thereof.

### BRIEF DESCRIPTION OF THE DRAWINGS

The invention will now be further described by way of example only with reference to the accompany drawings in which:

FIG. 1 illustrates narrow viewing angles of multiple views of a display panel resulted from large distance between the pixel elements and the barrier;

FIGS. 2A-2E illustrate a first embodiment of a method for forming a display panel according to the present invention;

FIGS. 3A-3E illustrate a second embodiment of a method for forming a display panel according to the present invention;

FIGS. 4A-4D illustrate a third embodiment of a method for forming a display panel according to the present invention;

FIGS. 5A-5D illustrate a fourth embodiment of a method for forming a display panel according to the present invention;

FIG. 6 illustrates one embodiment of a display panel according to the present invention; and

FIG. 7 illustrates wider viewing angles of multiple views of a display panel resulted from smaller distance between the pixel elements and the barrier according to the present invention.

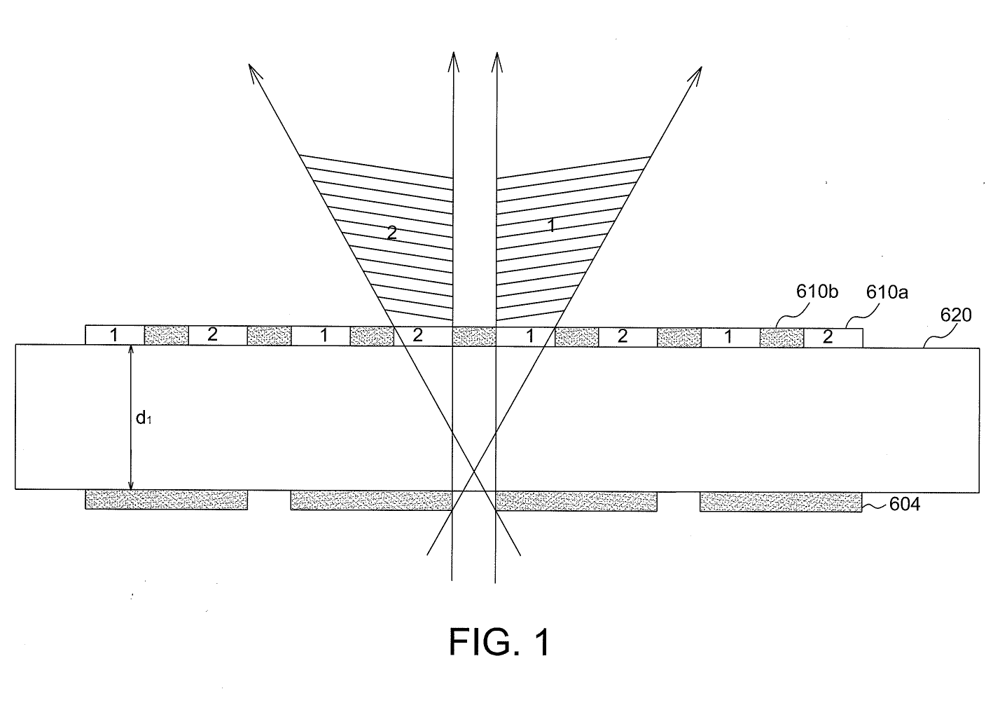

### DETAILED DESCRIPTION OF THE PREFERRED EMBODIMENTS

To obtain wider viewing angle for multiple views without complicating the manufacture, integrating the barrier into the pixel element module, such as the color filter plate, or the array circuit module, such as the array plate, is proposed by the present invention. As the distance between the pixel elements and the barrier is decreased, the viewing angle could be wider. Namely, the barrier patterns are first formed on a substrate, a thin planar structure is formed over the barrier patterns, and then the pixel elements and/or the array metals are formed over the planar structure. Accordingly, instead of a conventional substrate with a thickness of about 500 μm, a thin planar structure with a thickness between 10 μm and 200 μm is present between the pixel elements and the barrier. Therefore, the wide viewing angle, simplified manufacture and even reduced number of components are obtained.

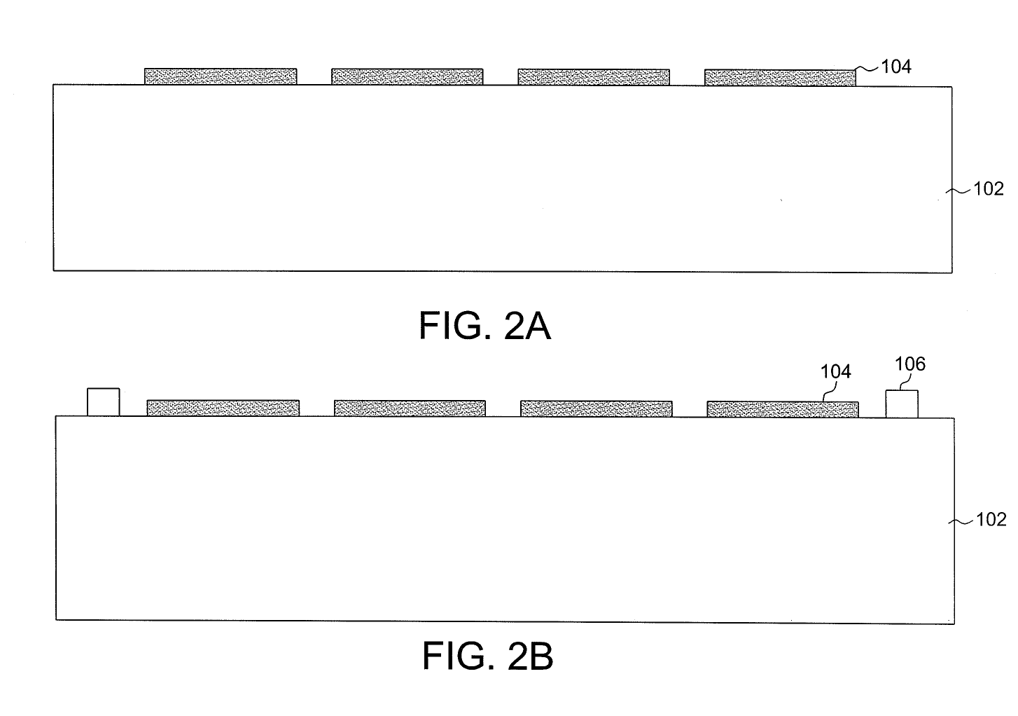

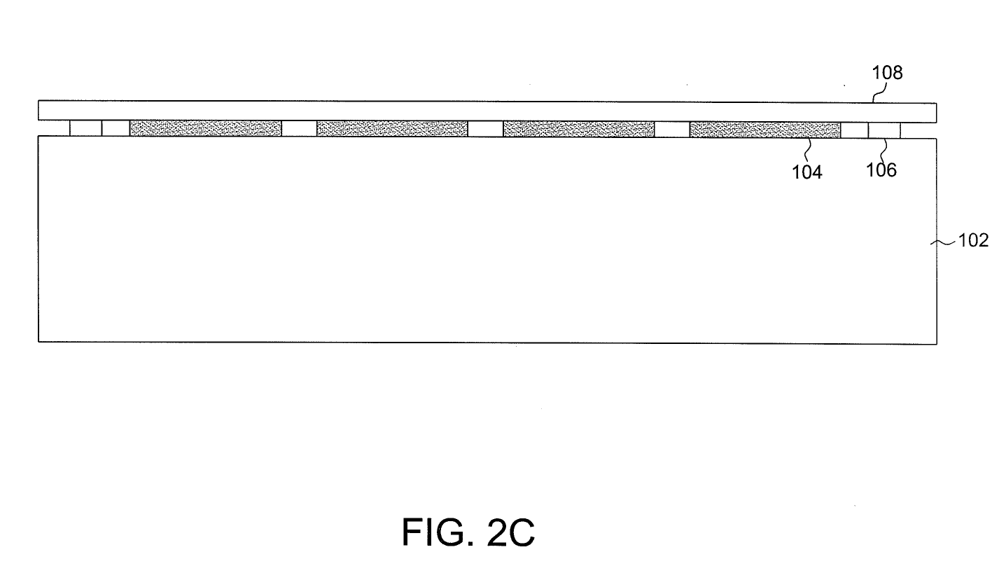

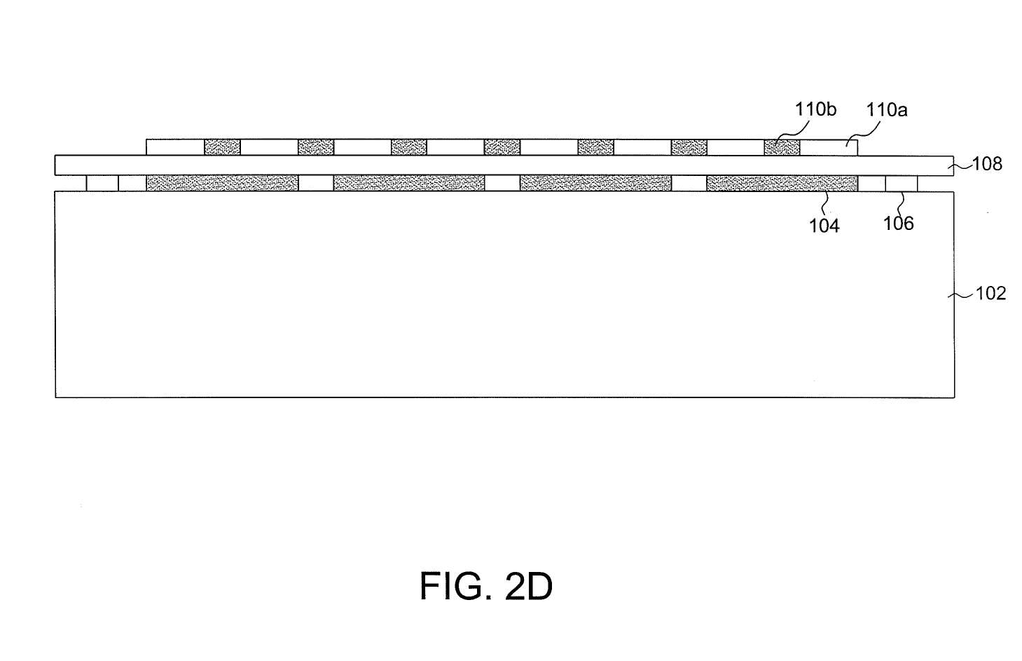

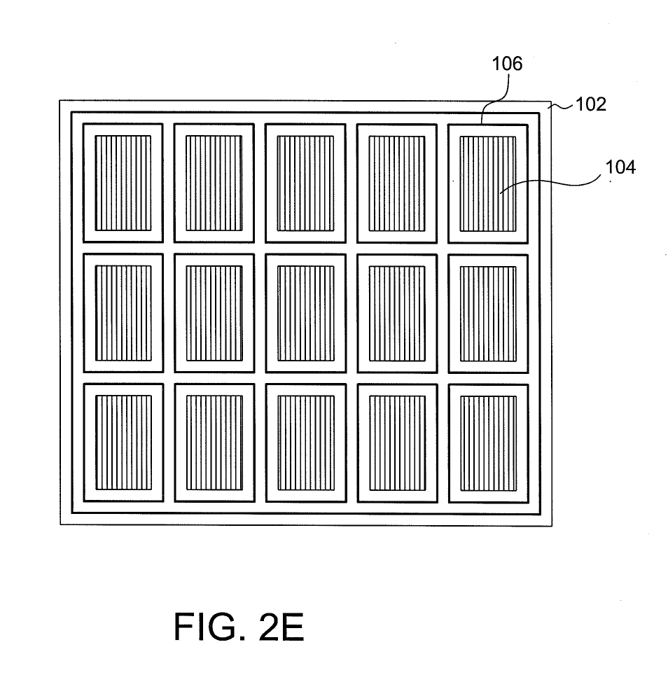

FIGS. 2A-2E illustrate a first embodiment of a method for forming a display panel according to the present invention. Referring to FIG. 2A, a substrate 102 is provided. A plurality of barrier patterns 104 are formed on the substrate 102. The substrate 102 may be made of glass. The barrier patterns 104 may be made of black resin, chromium, chromium oxide, chromium nitride, or a combination thereof. Referring to FIG. 2B, an adhesion material 106 is applied around the plurality of barrier patterns 104. A top view of multiple sets of barrier patterns 104 for multiple display panel cells is shown in FIG. 2E. In this embodiment, the adhesion material 106 is applied outside each set of barrier patterns 104, while it could be applied in other ways. The adhesion material 106 may be conventional sealants of display technology, optical glue, light curable glue, heat curable glue, or a combination thereof.

Referring to FIG. 2C, a planar structure 108 is placed over the plurality of barrier patterns 104. The planar structure 108 is adhered to the substrate 102 by the adhesion material 106. The planar structure 108 has a thickness between 10 μm and 200 μm. The step of placing the planar structure 108 may be performed under low pressure or vacuum, so that the planar structure 108 contacts the plurality of barrier patterns 104. The planar structure 108 may include plastic, glass, or a combination thereof. Then referring to FIG. 2D, a plurality of pixel elements 110a and 110b are formed over the planar structure 108. The pixel elements 110a may include color filters or light emitting diodes. The pixel elements 110b may include black matrix structures. Though pixel elements 110a and 110b are formed over the barrier patterns 104 in this embodiment, array metals or both of the pixel elements 110a and 110b and the array metals could be formed instead. Since instead of the thickness of the conventional substrate, such as 500 μm, the distance between the pixel elements 110a and 110b and the barrier patterns 104 is the thickness of the planar structure 108, such as between 10-200 μm, the viewing angle becomes wider. Besides, the manufacture is simplified.

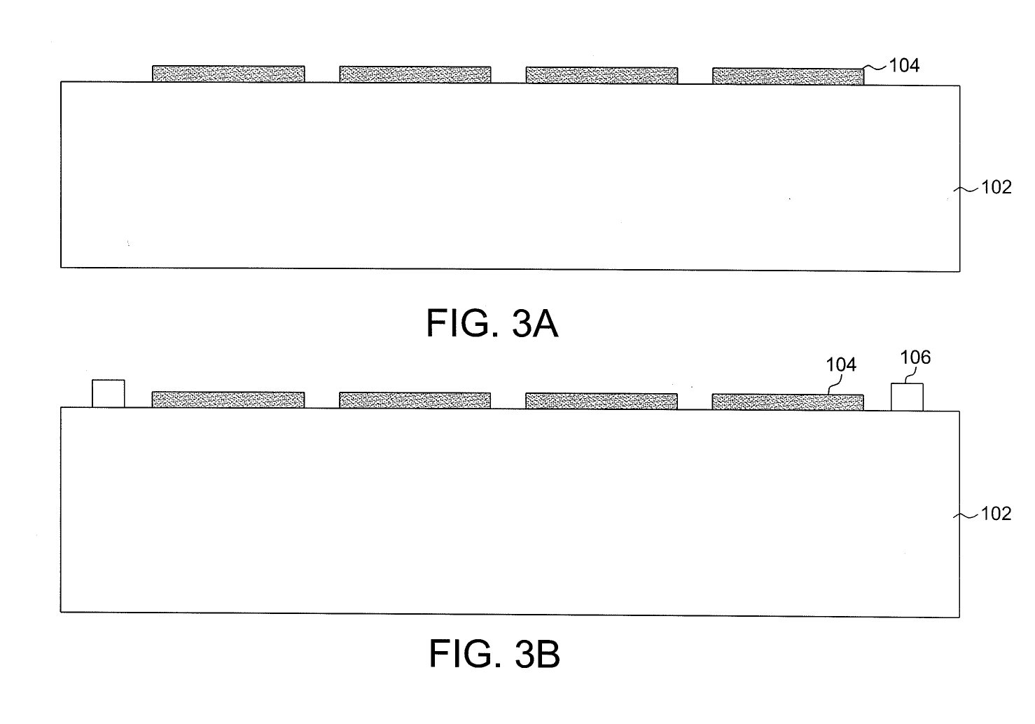

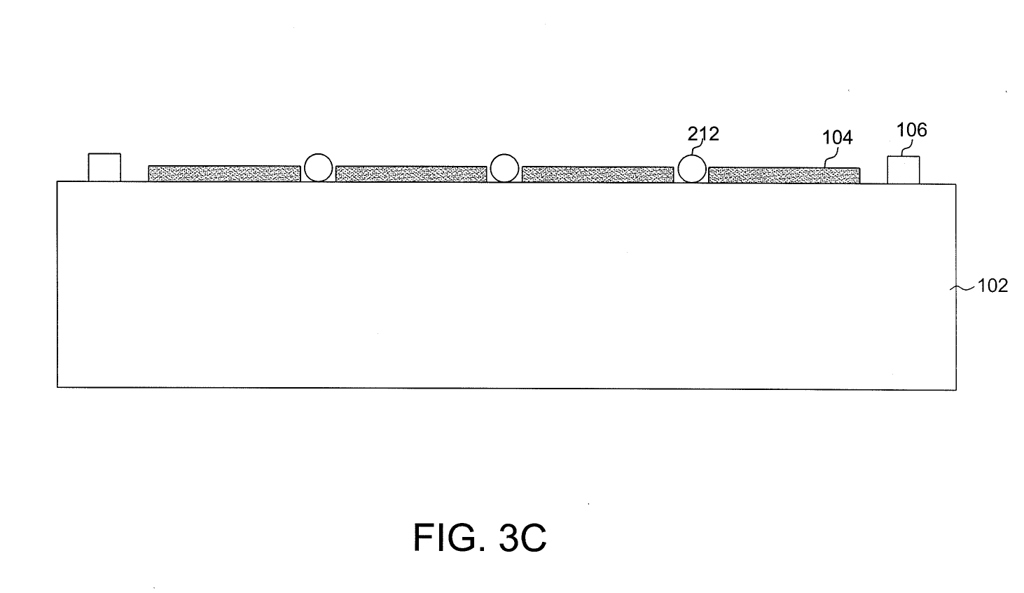

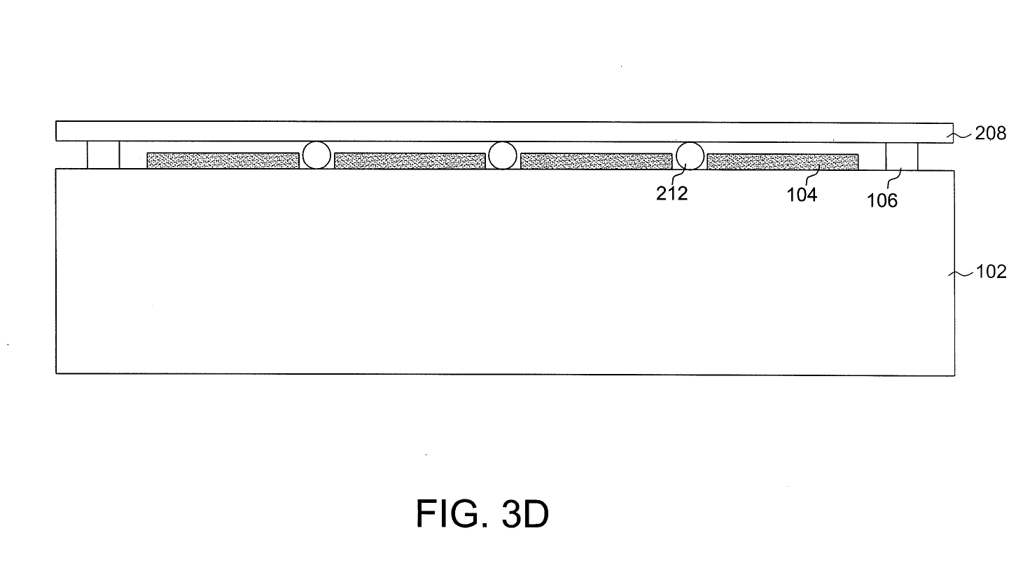

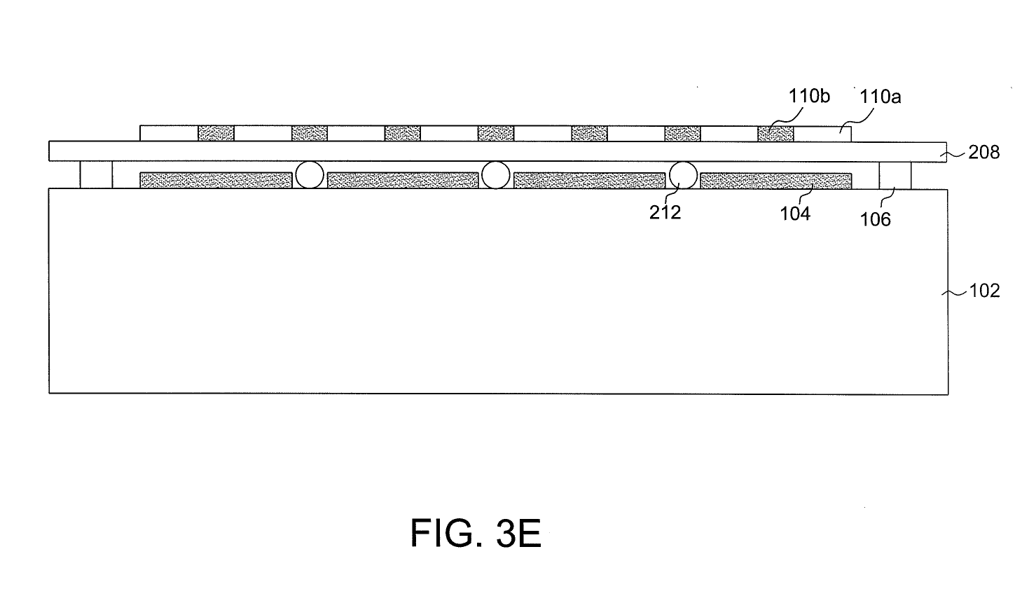

FIGS. 3A-3E illustrate a second embodiment of a method for forming a display panel according to the present invention. The steps of providing the substrate 102, forming the plurality of barrier patterns 104 and applying the adhesion material 106 in FIGS. 3A-3B are similar to those shown in FIGS. 2A-2B. Nevertheless, as shown in FIG. 3C, a plurality of spacers or photospacers 212 may be disposed on the substrate 102 before placing the planar structure 208 over the plurality of barrier patterns 104. The spacers or photospacers 212 may create a uniform distance between the substrate 102 and the planar structure 208 for facilitating the subsequent processes. Referring to FIG. 3D, the planar structure 208 is placed over the plurality of barrier patterns 104. The planar structure 208 is adhered to the substrate 102 by the adhesion material 106. The planar structure 208 has a thickness between 10 μm and 200 μm. The planar structure 208 may include plastic, glass, or a combination thereof. Next, the step of forming the plurality of pixel elements 110a and 110b over the planar structure 208 shown in FIG. 3E is similar to that shown in FIG. 2D and not elaborated herein. Since instead of the thickness of the conventional substrate, such as 500 μm, the distance between the pixel elements 110a and 110b and the barrier patterns 104 is the combination of the thickness of the planar structure 208, such as between 10-200/m, and the diameter height of the spacers or photospacers 212, such as 0.5-5 μm, the viewing angle becomes wider. Besides, the manufacture is simplified.

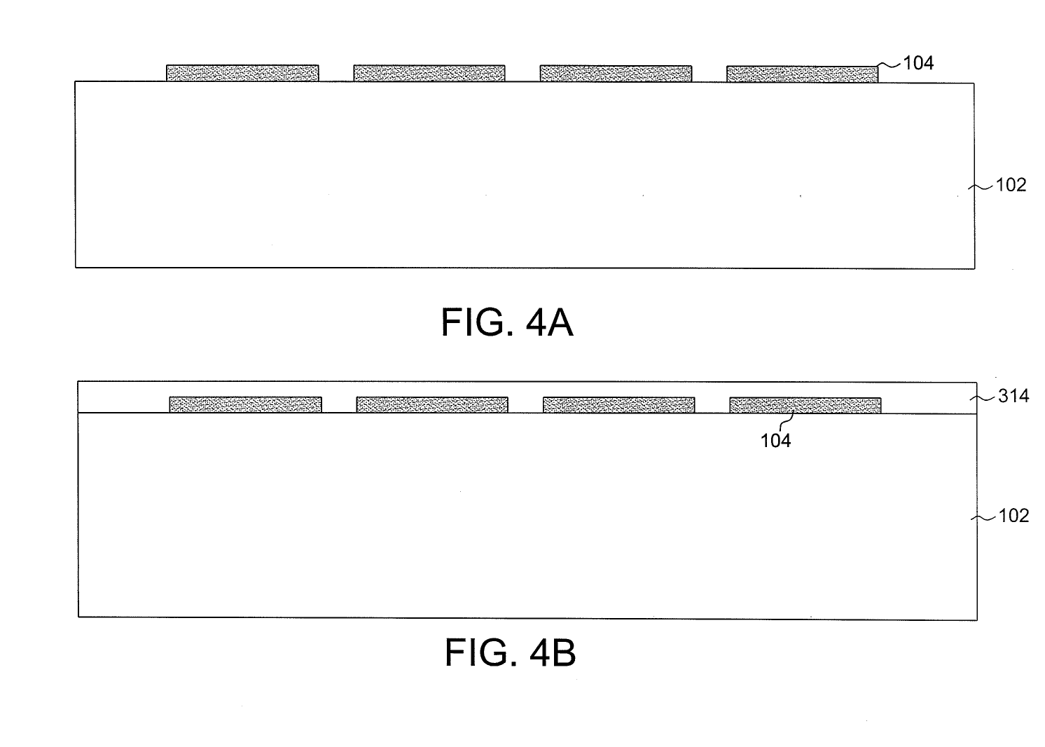

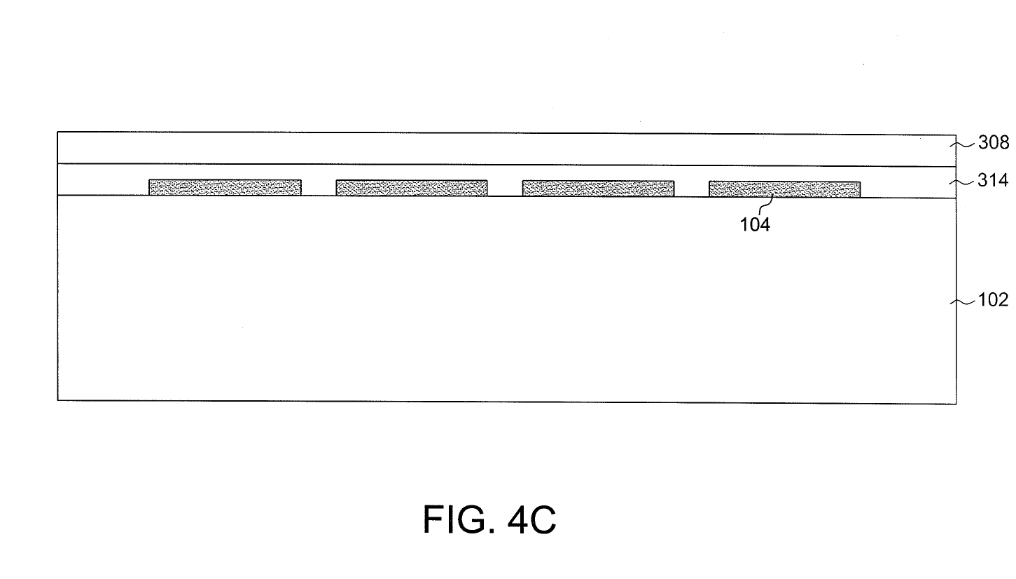

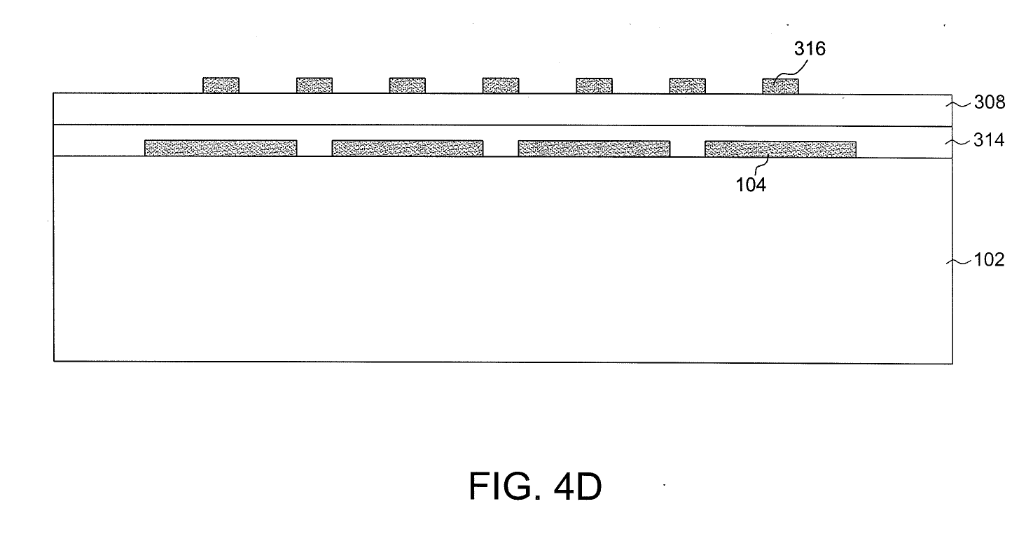

FIGS. 4A-4D illustrate a third embodiment of a method for forming a display panel according to the present invention. The steps of providing the substrate 102 and forming the plurality of barrier patterns 104 in FIG. 4A are similar to those shown in FIG. 2A and not elaborated herein. Now referring to FIG. 4B, an adhesion material 314 is applied on the plurality of barrier patterns 104. The adhesion material 314 may include optical glue, light curable glue, heat curable glue, a combination thereof, or any other adhesion material that could withstand the temperatures corresponding to the subsequent processes. Then referring to FIG. 4C, a planar structure 308 is placed on the adhesion material 314. The planar structure 308 has a thickness between 10 μm and 200 μm. The planar structure 308 may include plastic, glass, or a combination thereof. As the planar structure 308 is plastic, the step of placing the planar structure 308 on the adhesion material 314 may include hot pressing the planar structure 308 toward the plurality of barrier patterns 104.

Next, as shown in FIG. 4D, a plurality of array metals 316 are formed over the planar structure 308. Though array metals 316 are formed over the barrier patterns 104 in this embodiment, pixel elements or both of them could be formed instead. In this embodiment, the distance between the array metals 316 and the barrier patterns 104 is reduced, so that the distance between the subsequently formed pixel elements and the barrier patterns 104 would be reduced, and the viewing angle would become wider. Besides, the manufacture is simplified.

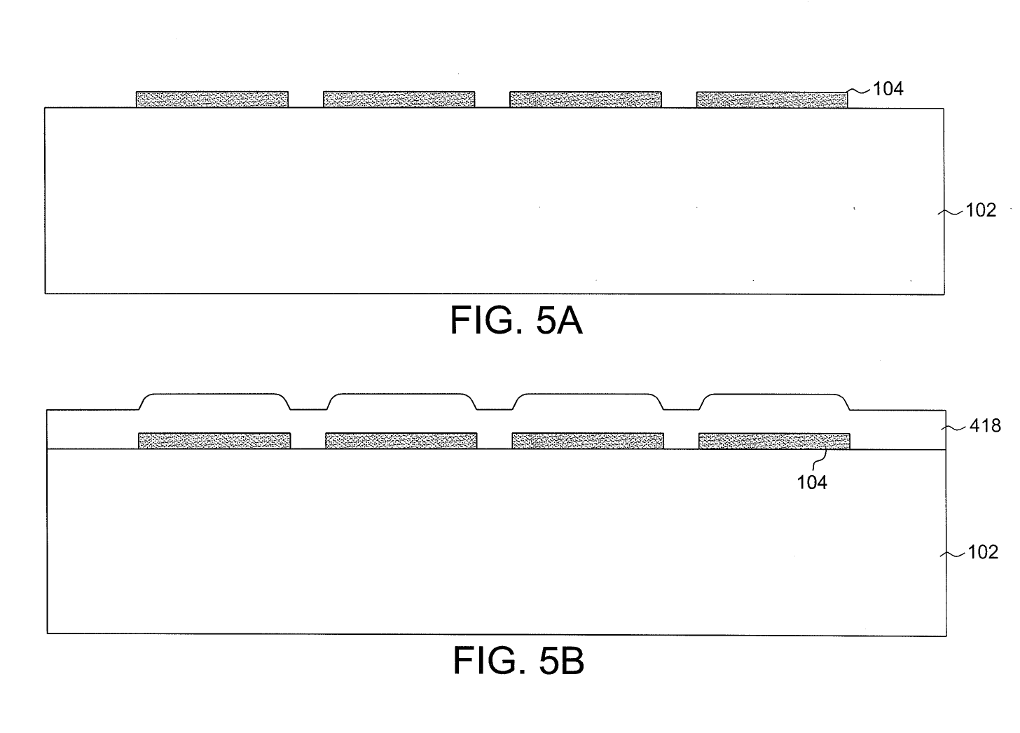

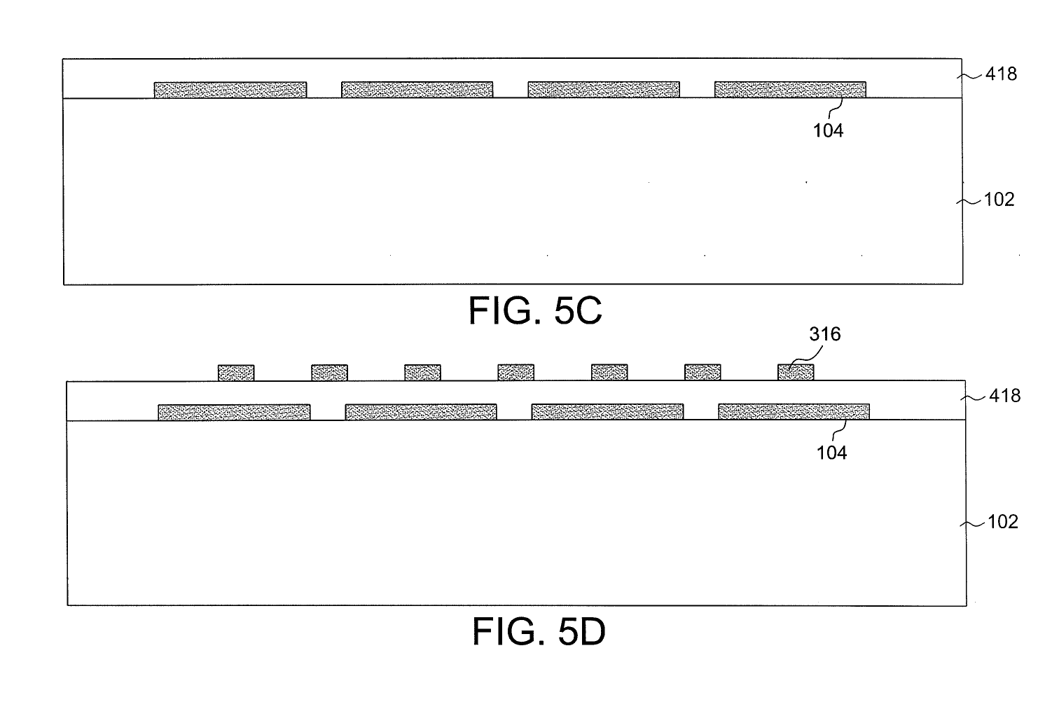

FIGS. 5A-5D illustrate a fourth embodiment of a method for forming a display panel according to the present invention. The steps of providing the substrate 102 and forming the plurality of barrier patterns 104 in FIG. 5A are similar to those shown in FIG. 2A and not elaborated herein. Next, referring to FIG. 5B, a planar structure 418 is deposited over the plurality of barrier patterns 104. The planar structure 418 may include epoxy, UV or thermal curable acrylates, overcoat layers used for color filter leveling, adapted overcoat materials, any other organic transparent materials, or a combination thereof. The step of depositing the planar structure 418 over the plurality of barrier patterns 104 may include screen-printing, spin coating, evaporation, sputtering, or a combination thereof. Referring to FIG. 5C, the planar structure 418 may be polished for facilitating subsequent processes. The planar structure 418 has a thickness between 10 μm and 200 μm. The step of forming a plurality of array metals 316 over the planar structure 418 in FIG. 5D is similar to that shown in FIG. 4D and not elaborated herein. In this embodiment, the distance between the array metals 316 and the barrier patterns 104 is reduced, so that the distance between the subsequently formed pixel elements and the barrier patterns 104 would be reduced, and the viewing angle would become wider. Besides, the manufacture is simplified.

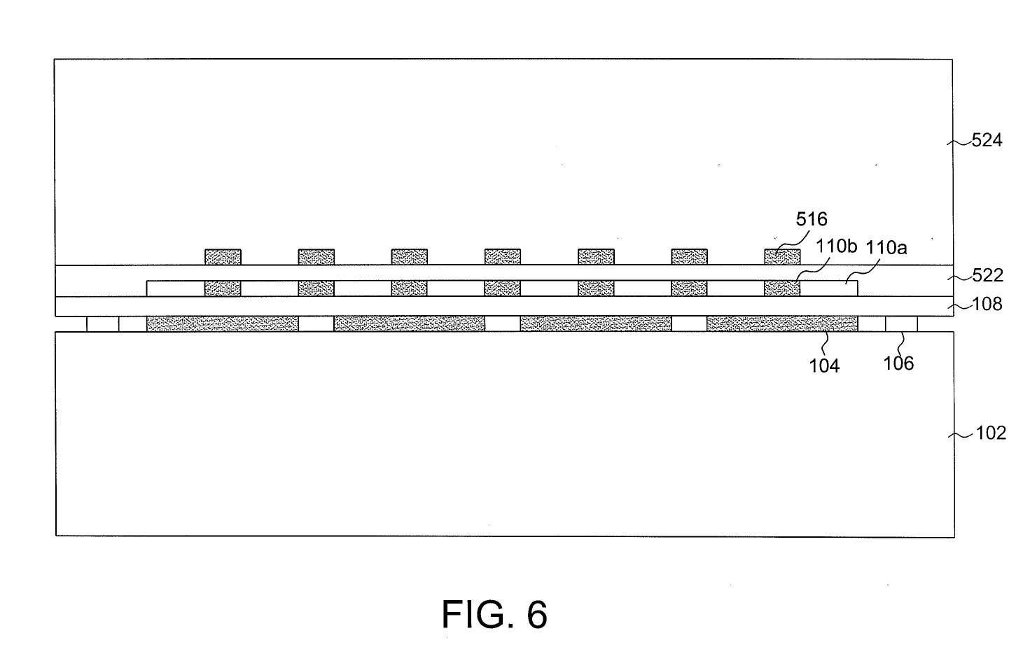

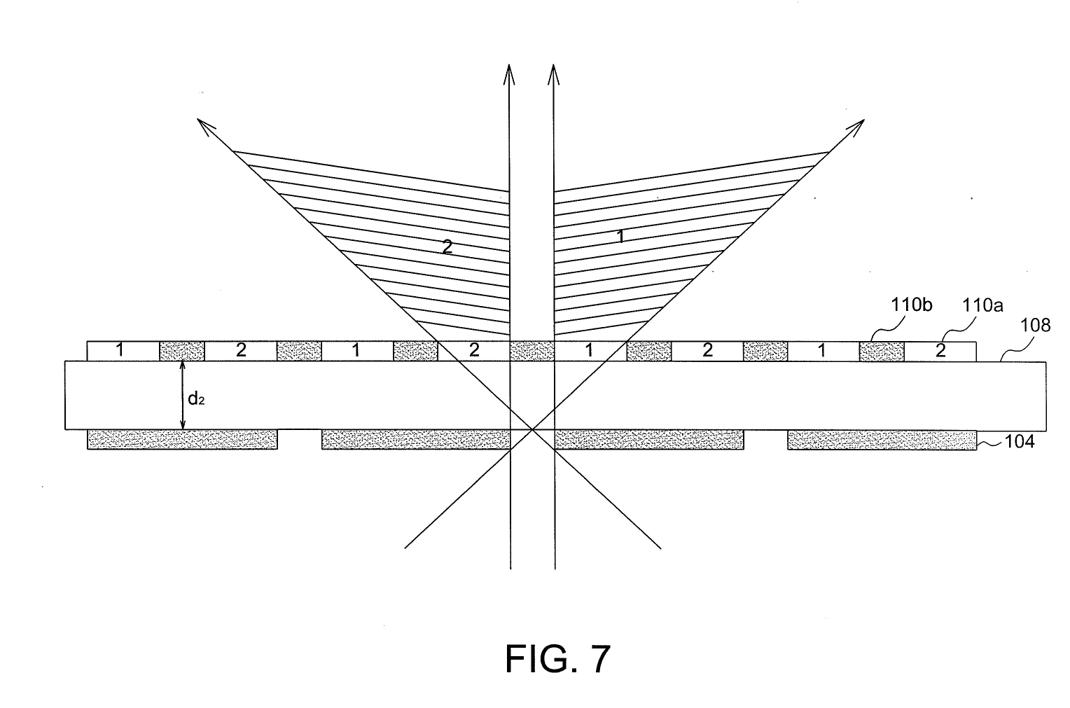

FIG. 6 illustrates one embodiment of a display panel according to the present invention. The steps of providing the substrate 102, forming the barrier patterns 104, applying the adhesion material 106, placing the planar structure 108, and forming the pixel elements 110a and 110b are similar to those shown in FIGS. 2A-2D and not elaborated herein. A layered structure 522 which may include a common electrode and/or leveling material for the pixel elements 110a and 110b may be formed on the pixel elements 110a and 110b. Thus formed structure could be assembled with an array plate having a plurality of array metals 516. The array metals 516 may be formed on a substrate 524. As a backlight unit being attached under the barrier patterns 104 or over the array metals 516, a display panel with rear barrier or front barrier could be realized. Referring to FIG. 7, wider viewing angles of multiple views of a display panel resulted from smaller distance between the pixel elements 110a and 110b and the barrier patterns 104 according to the present invention. Since instead of the thickness of the conventional substrate, such as 500 μm, the distance between the pixel elements 110a and 110b and the barrier patterns 104 is the thickness of the planar structure 108, such as between 10-200 μm, the viewing angle becomes wider. Besides, the manufacture is simplified.

The above description is only for preferred embodiments, but not to limit the scope of the present invention. Any other equivalent changes or modifications performed with the spirit disclosed by the present invention should be included in the appended claims.

We claim:

1. A method for forming a display panel, comprising:
providing a substrate;
forming a plurality of barrier patterns on said substrate;
forming a planar structure over said plurality of barrier patterns; and
forming a plurality of pixel elements and/or a plurality of array metals over said planar structure;
wherein said planar structure has a thickness between 10 μm and 200 μm.

2. The method according to claim 1, wherein said step of forming a planar structure over said plurality of barrier patterns comprises:
applying an adhesion material around said plurality of barrier patterns; and
placing said planar structure over said plurality of barrier patterns;
wherein said planar structure is adhered to said substrate by said adhesion material.

3. The method according to claim 2, wherein said step of placing said planar structure over said plurality of barrier patterns is performed under low pressure or vacuum, so that said planar structure contacts said plurality of barrier patterns.

4. The method according to claim 2, further comprising the following step before said step of placing said planar structure over said plurality of barrier patterns:
disposing a plurality of spacers or photospacers on said substrate.

5. The method according to claim 1, wherein said step of forming a planar structure over said plurality of barrier patterns comprises:
applying an adhesion material on said plurality of barrier patterns; and
placing said planar structure on said adhesion material.

6. The method according to claim 5, wherein said planar structure is plastic and said step of placing said planar structure on said adhesion material comprises:
hot pressing said planar structure toward said plurality of barrier patterns.

7. The method according to claim 1, wherein said step of forming a planar structure over said plurality of barrier patterns comprises:
depositing said planar structure over said plurality of barrier patterns.

8. The method according to claim 7, wherein said step of forming a planar structure over said plurality of barrier patterns further comprising:
polishing said planar structure.

9. The method according to claim 8, wherein said step of depositing said planar structure over said plurality of barrier patterns comprises screen printing, spin coating, evaporation, sputtering, or a combination thereof.

10. A display panel, comprising:
a substrate;
a plurality of barrier patterns on said substrate;
a planar structure over said plurality of barrier patterns; and
a plurality of pixel elements and/or a plurality of array metals over said planar structure;
wherein said planar structure has a thickness between 10 μm and 200 μm.

11. The display panel according to claim 10, further comprising:
an adhesion material around said plurality of barrier patterns;
wherein said planar structure is adhered to said substrate by said adhesion material.

12. The display panel according to claim 11, wherein said planar structure contacts said plurality of barrier patterns.

13. The display panel according to claim 12, further comprising:
a plurality of spacers or photospacers disposed on said substrate.

14. The display panel according to claim 12, wherein said planar structure comprises plastic, glass, or a combination thereof.

15. The display panel according to claim 11, further comprising:
an adhesion material on said plurality of barrier patterns;
wherein said planar structure is placed on said adhesion material.

16. The display panel according to claim 15, wherein said adhesion material comprises optical glue, light curable glue, heat curable glue, or a combination thereof.

17. The display panel according to claim 15, wherein said planar structure is plastic and hot pressed toward said plurality of barrier patterns.

18. The display panel according to claim 10, wherein said planar structure is deposited over said plurality of barrier patterns.

19. The display panel according to claim 18, wherein said planar structure is further polished.

20. The display panel according to claim 18, wherein said planar structure comprises organic transparent material.
